(19) United States
(12) Patent Application Publication
(10) Pub. No.: US 2026/0262493 A1
(43) Pub. Date: Sep. 3, 2026

(54) SEMICONDUCTOR DEVICE AND POWER CONVERSION DEVICE

(71) Applicant: HITACHI ASTEMO, LTD., Hitachinaka-shi, Ibaraki (JP)

(72) Inventors: Ning TANG, Tokyo (JP); Nobutake TSUYUNO, Tokyo (JP); Yujiro KANEKO, Hitachinaka-shi, Ibaraki (JP)

(73) Assignee: HITACHI ASTEMO, LTD., Hitachinaka-shi, Ibaraki (JP)

(21) Appl. No.: 18/718,493

(22) PCT Filed: Dec. 15, 2022
(86) PCT No.: PCT/JP2022/046286

§ 371 Date: Jun. 11, 2024

(30) Foreign Application Priority Data
Dec. 16, 2021 (JP) 2021-204353

(51) Int. Cl. H10W 40/20; H10W 74/10

(52) U.S. Cl. CPC H10W 40/242; H10W 74/111

(57) ABSTRACT

A semiconductor device according to the present invention is provided with: a plurality of electrical circuit bodies, each of which has a semiconductor element; a pair of heat dissipation members, between which the plurality of electrical circuit bodies are sandwiched from both surface sides; a first heat transfer member which is arranged between one of the heat dissipation members and one surface of each of the plurality of electrical circuit bodies; and a second heat transfer member which is arranged between the other one of the heat dissipation members and the other surface of each of the plurality of electrical circuit bodies. With respect to this semiconductor device, the elongation of the first heat transfer member at the time of separation is higher than the elongation of the second heat transfer member at the time of separation.

### TECHNICAL FIELD

The present invention relates to a semiconductor device and a power conversion device.

### BACKGROUND ART

A power conversion device that causes a power semiconductor element to perform a switching operation has high conversion efficiency, and thus is widely used for consumer use, in-vehicle use, railway use, transformation equipment, and the like. Since the power semiconductor element generates heat by energization, a heat dissipation member is provided in a semiconductor device in which the power semiconductor element is built.

PTL 1 discloses a semiconductor device in which a heat dissipation material (heat conduction member) is provided between the semiconductor device and a heat dissipation member, and heat is conducted to the heat dissipation member through the heat dissipation material.

### CITATION LIST

### Patent Literature

PTL 1: JP 2019-102646 A

### SUMMARY OF INVENTION

### Technical Problem

The technique disclosed in PTL 1 has a problem that the reliability of the semiconductor device for displacement caused by vibration or a thermal cycle is lowered.

### Solution to Problem

According to the present invention, a semiconductor device includes a plurality of electric circuit bodies each having a semiconductor element, a pair of heat dissipation members sandwiching the plurality of electric circuit bodies from both surfaces thereof, a first heat conduction member disposed between one of the heat dissipation members and one surface of the plurality of electric circuit bodies, and a second heat conduction member disposed between another of the heat dissipation members and another surface of the plurality of electric circuit bodies, in which an elongation until peeling of the first heat conduction member is larger than an elongation until peeling of the second heat conduction member.

### Advantageous Effects of Invention

According to the present invention, the reliability of the semiconductor device for displacement caused by vibration or a thermal cycle is improved.

### BRIEF DESCRIPTION OF DRAWINGS

FIG. 1 is a plan view of a semiconductor device.

FIG. 2 is a cross-sectional view of the semiconductor device taken along line X-X.

FIG. 3 is a cross-sectional view of the semiconductor device taken along line Y-Y.

FIG. 4 is a cross-sectional perspective view of an electric circuit body.

FIGS. 5(a), 5(b), and 5(c) are cross-sectional views for describing manufacturing steps of the semiconductor device.

FIGS. 6(d), 6(e), and 6(f) are cross-sectional views for describing manufacturing steps of the semiconductor device.

FIG. 7 is a cross-sectional view of semiconductor device in Comparative Example 1.

FIG. 8 is a cross-sectional view of a semiconductor device in Comparative Example 2.

FIG. 9 is a cross-sectional view of semiconductor device in Modification Example 1.

FIG. 10 is a cross-sectional view of a semiconductor device in Modification Example 2.

FIG. 11 is a semi-transparent plan view of the semiconductor device.

FIG. 12 is a circuit diagram of the semiconductor device.

FIG. 13 is a circuit diagram of a power conversion device 200 using the semiconductor device.

FIG. 14 is an external perspective view of the power conversion device.

FIG. 15 is a cross-sectional view of the power conversion device taken along line XV-XV.

### DESCRIPTION OF EMBODIMENTS

Hereinafter, an embodiment of the present invention will be described with reference to the drawings. The following description and drawings are examples for describing the present invention, and are omitted and simplified as appropriate for clarity of description. The present invention can be carried out in various other forms. Unless otherwise specified, each component may be singular or plural.

Positions, sizes, shapes, ranges, and the like of the components illustrated in the drawings may not represent actual positions, sizes, shapes, ranges, and the like in order to facilitate understanding of the invention. Therefore, the present invention is not necessarily limited to the positions, sizes, shapes, ranges, and the like illustrated in the drawings.

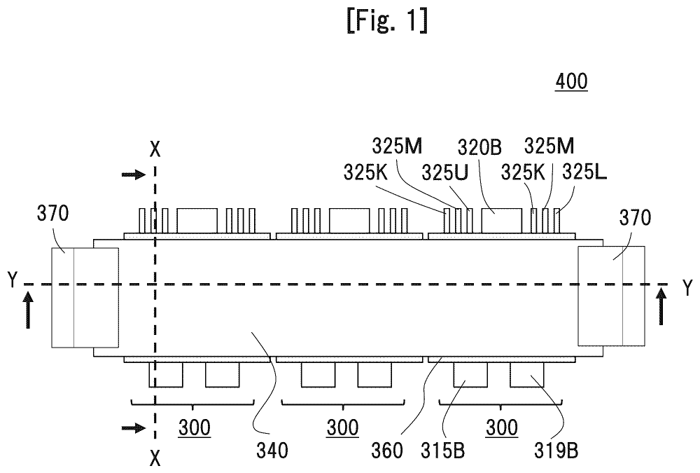

FIG. 1 is a plan view of a semiconductor device 400.

The semiconductor device 400 includes a plurality of electric circuit bodies 300, a heat dissipation member 340, and heat conduction members 453 and d 454 which will be described later. FIG. 1 illustrates, as an example, a semiconductor device 400 including electric circuit bodies 300 for three modules.

The electric circuit body 300 has a power semiconductor element built therein and causes the power semiconductor element to perform a switching operation so as to convert a DC current and an AC current, and generates heat by the switching operation. The heat dissipation member 340 cools the electric circuit body 300 that has generated heat, and cools the inside of the heat dissipation member 340 by circulating a coolant. As the coolant, water, an antifreeze liquid in which ethylene glycol is mixed with water, or the like is used. Although details of the heat conduction members 453 and 454 will be described later, the heat conduction members 453 and 454 are disposed between the heat dissipation member 340 and the electric circuit body 300.

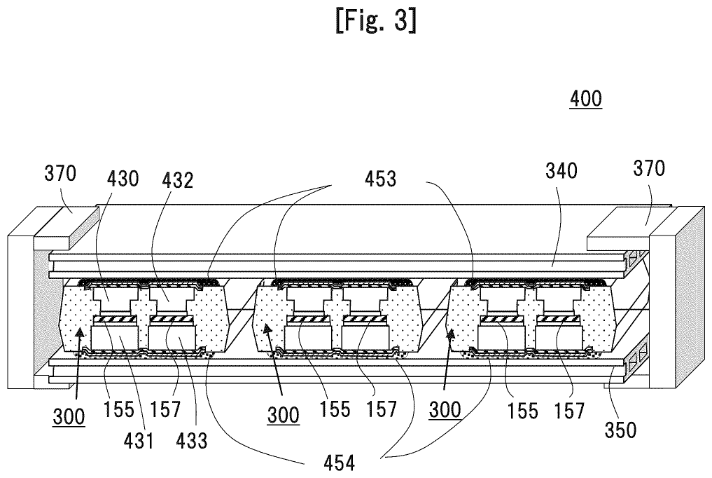

The semiconductor device 400 includes a pressurizing member 370 that pressurizes the electric circuit bodies 300 for three modules from both surfaces. The pressurizing member 370 abuts on the outer side surfaces of a pair of heat dissipation members 340 and 350 (see FIG. 3) and sandwiches the pair of heat dissipation members 340 and 350 to pressurize the heat conduction members 453 and 454. The pressurizing member 370 is, for example, a leaf spring, a clip, or the like formed in a U shape, and may be any member having a pressurizing elastic force in a sandwiching direction.

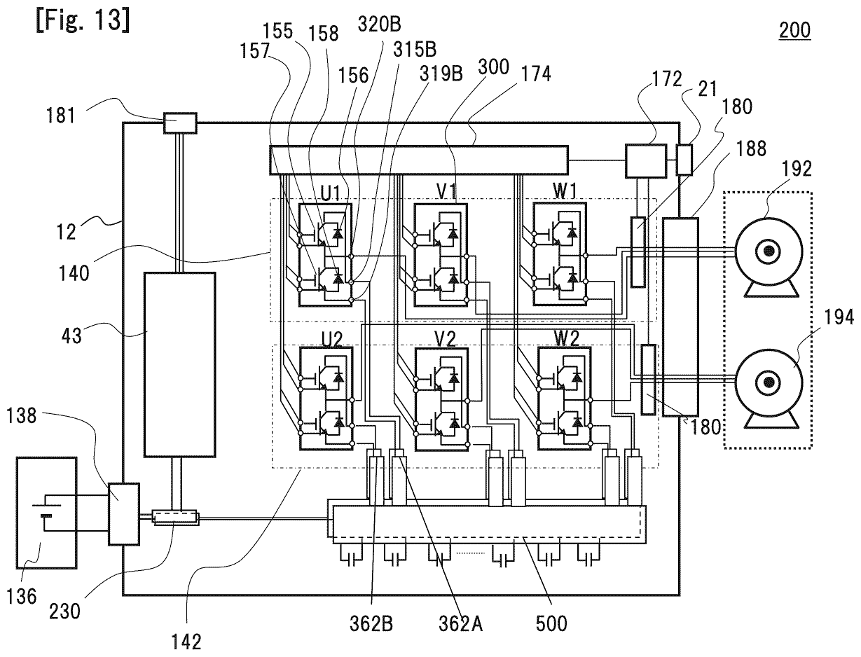

The electric circuit body 300 includes power terminals through which a large current flows, such as a positive-electrode-side terminal 315B and a negative-electrode-side terminal 319B connected to a capacitor module 500 (see FIG. 13) of a DC circuit, and an AC side terminal 320B connected to motor generators 192 and 194 (see FIG. 13) of an AC circuit. The semiconductor device further includes signal terminals and the like that are drawn from the power semiconductor element and are used for control of the semiconductor device, such as a lower arm gate terminal 325L, a mirror emitter signal terminal 325M, a Kelvin emitter signal terminal 325K, an upper arm gate terminal 325U, a mirror emitter signal terminal 325M, and a Kelvin emitter signal terminal 325K.

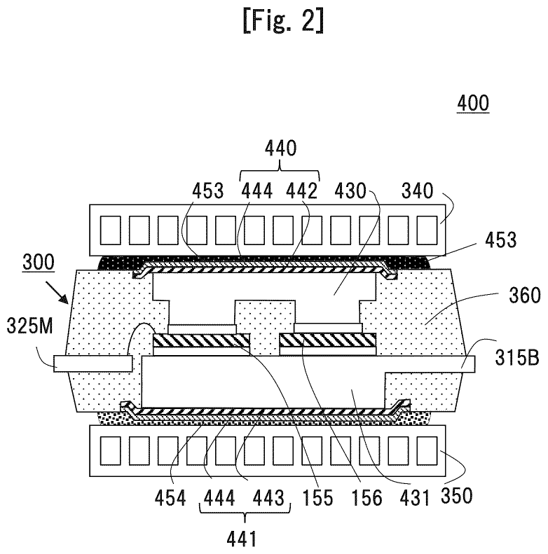

FIG. 2 is a cross-sectional view of the semiconductor device 400 illustrated in FIG. 1, taken along line X-X illustrated in FIG. 1. FIG. 3 is a cross-sectional view of the semiconductor device 400 illustrated in FIG. 1, taken along line Y-Y illustrated in FIG. 1.

As a first power semiconductor element forming an upper arm circuit, an active element 155 and a diode 156 are provided. For the active element, Si, SiC, GaN, GaO, C, or the like can be used. When a body diode of the active element is used, a separate diode may be omitted. The collector side of the first power semiconductor elements 155 and 156 is bonded to a second conductor plate 431. For this bonding, solder or sintered metal may be used. In addition, the conductor plate is not particularly limited as long as the conductor plate is made of a material having high electrical conductivity and thermal conductivity, and a copper-based or aluminum-based material is desirable. These materials may be used singly, but plating with Ni, Ag, or the like may be performed in order to improve or bondability to solder or sintered metal. A first conductor plate 430 is bonded to the emitter side of the first power semiconductor elements 155 and 156. The first conductor plate 430 has a recess at the outer periphery of a region connected to the power semiconductor element in order to secure an insulation distance.

As a second power semiconductor element forming a lower arm circuit, an active element 157 and a diode 158 are provided. The collector side of the second power semiconductor elements 157 and 158 is bonded to a fourth conductor plate 433. A third conductor plate 432 is bonded to the emitter side of the second power semiconductor elements 157 and 158.

The conductor plates 430, 431, 432, and 433 not only function to conduct a current but also function as a heat transfer member that transfers heat generated by the power semiconductor elements 155, 156, 157, and 158 to the emitter-side heat dissipation member 340 and the collector-side heat dissipation member 350. Since the conductor plates 430, 431, 432, and 433 have potentials different from the potentials of the heat dissipation members 340 and 350, sheet-shaped members 440 and 441 having resin insulating layers 442 and 443 are interposed therebetween. Heat conduction members 453 and 454 for reducing contact thermal resistance are provided between the sheet-shaped members 440 and 441, and the heat dissipation members 340 and 350. The power semiconductor elements 155, 156, 157, and 158, the conductor plates 430, 431, 432, and 433, and the sheet-shaped members 440 and 441 are sealed with a sealing member 360 by transfer molding.

The resin insulating layers 442 and 443 of the sheet-shaped members 440 and 441 are not particularly limited as long as the resin insulating layers 442 and 443 have adhesiveness to the conductor plates 430, 431, 432, and 433, and an epoxy resin-based resin insulating layer in which a powdery inorganic filler is dispersed is desirable. This is because of the favorable balance between the adhesiveness and the heat dissipation. The sheet-shaped members 440 and 441 may be resin insulating layers singly, and it is desirable to provide a metal foil 444 on the side in contact with the heat conduction members 453 and 454. In a transfer molding step, when the sheet-shaped members 440 and 441 are mounted on a mold, a release sheet or the metal foil 444 is provided on a contact surface of the sheet-shaped members 440 and 441 with the mold in order to prevent adhesion to the mold. Since the release sheet has poor thermal conductivity, a step of peeling off the release sheet after transfer molding is required. However, in the case of the metal foil, by selecting copper-based or aluminum-based metal having high thermal conductivity, the release sheet can be used without peeling off after transfer molding. By performing transfer molding with the sheet-shaped members 440 and 441, the end portions of the sheet-shaped members 440 and 441 are covered with the sealing member 360, so that there is an effect of improving reliability.

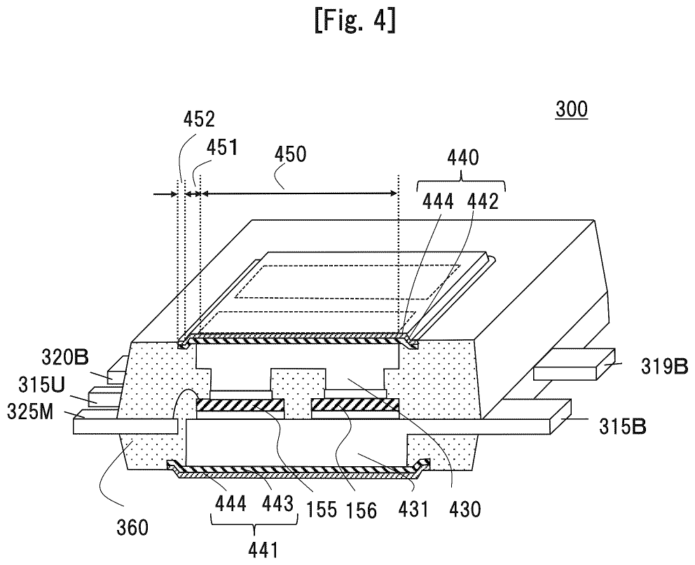

FIG. 4 is a cross-sectional perspective view of the electric circuit body 300.

A margin portion 451 that generates a step and is convex is provided for a buried portion 452 in which the end portions of the sheet-shaped members 440 and 441 are covered with the sealing member 360. As a result, there is an effect of stopping the sealing member 360 and resin burrs made of resin components of the sealing member 360 from flowing between the sheet-shaped members 440 and 441 and the mold. Although the sheet-shaped members 440 and 441 are vacuum-attracted to the transfer mold, the adsorption force is much smaller than the molding pressure for injecting transfer mold resin.

When the inside of a cavity into which the sealing member 360 is injected is evacuated for vacuum molding, the attraction force is further weakened. Therefore, the sealing member 360 and the resin burrs made of the resin components in the sealing member 360 flow between the sheet-shaped members 440 and 441 and the transfer mold from the outer peripheral portions of the sheet-shaped members 440 and 441. At this time, when the mold is processed so that a step is generated at the margin portion 451 that is convex slightly inside the outer peripheral portions of the sheet-shaped members 440 and 441, the sealing member 360 and the resin burr are stopped by this step.

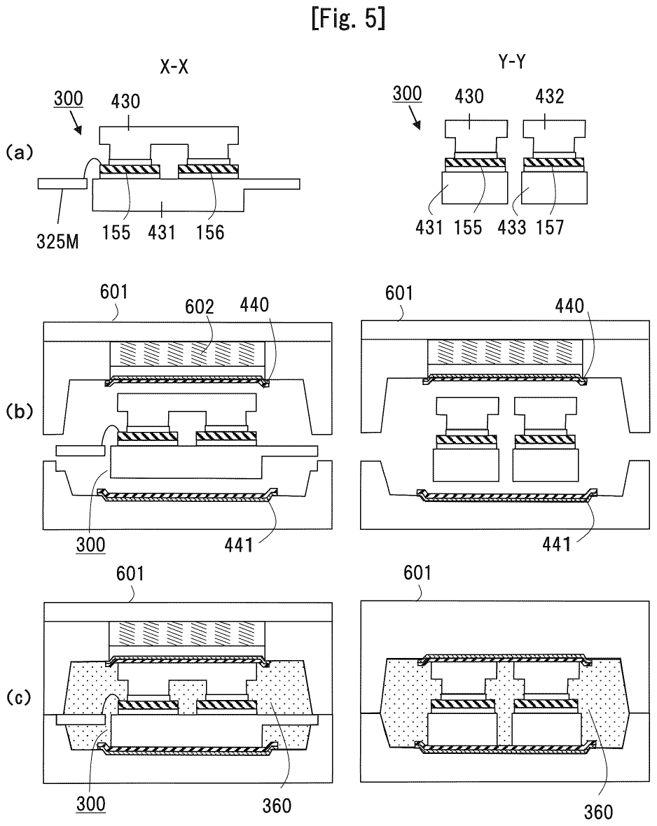

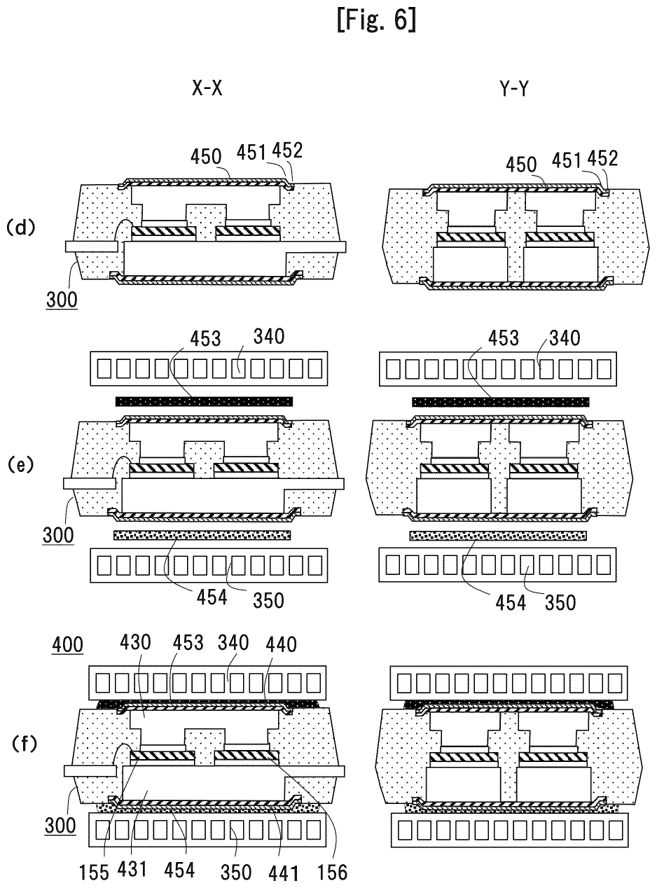

FIGS. 5(a) to 5(c) and FIGS. 6(d) to 6(f) are cross-sectional views for describing manufacturing steps of the semiconductor device 400. An X-X cross section of one module is illustrated on the left side of each drawing, and a Y-Y cross section is illustrated on the right side of each drawing.

FIG. 5(a) illustrates a solder connection step and a wire bonding step. The collector side of the power semiconductor elements 155, 156, 157, and 158 such as active elements and diodes is connected to the conductor plates 430, 431, 432, and 433, and a mirror emitter electrode of the active element is connected to the mirror emitter signal terminal 325M by wire bonding.

FIG. 5(b) illustrates a transfer molding step. A transfer molding device 601 includes a mechanism for vacuum-attracting the sheet-shaped members 440 and 441 to a mold and a vacuum degassing mechanism. The sheet-shaped members 440 and 441 are installed in the mold heated to a constant temperature state of 175° C. in advance, and held by vacuum attraction. The electric circuit body 300 heated to 175° C. in advance is set in the mold while being spaced apart from the sheet-shaped members 440, 441. Then, upper and lower molds are pressed at positions where the sheet-shaped members 440 and 441 do not come into contact with the electric circuit body 300, and only packings installed in the upper and lower molds (not illustrated) are brought into contact with each other. Then, the inside of a mold cavity is evacuated. When the evacuation is completed so that the air pressure becomes equal to or less than the predetermined air pressure, the packing is further crushed, and the upper and lower molds are completely clamped. At this time, the sheet-shaped members 440 and 441 are in contact with the electric circuit body 300. In a vacuum state, the sheet-shaped members 440 and 441 come into contact with the electric circuit body 300 and come into close contact with the electric circuit body 300 by a pressurization force by a spring 602 of the transfer molding device 601, so that the sheet-shaped members can come into close contact with the electric circuit body 300 without involving voids.

FIG. 5(c) illustrates a sealing step. The sealing member 360 is injected into the mold cavity to seal the electric circuit body 300.

FIG. 6(d) is a view illustrating a state in which the sealed electric circuit body 300 is taken out. A step is formed between the buried portion 452 and the margin portion 451. No step is formed between the heat dissipation surface portion 450 and the margin portion 451.

FIG. 6(e) illustrates a step of installing the heat conduction members 453 and 454 and the heat dissipation members 340 and 350 on the electric circuit body 300. The semiconductor device 400 is manufactured by pressing the heat dissipation members 340 and 350 against both surfaces of the electric circuit body 300 through the heat conduction members 453 and 454.

FIG. 6(f) is a cross-sectional view of the semiconductor device 400. The semiconductor device 400 manufactured through the above steps will be described.

The heat conduction members 453 and 454 in the present embodiment will be described below with reference to FIG. 6(f).

First, the emitter-side heat dissipation member 340 and the collector-side heat dissipation member 350 are desirably made of aluminum series having high thermal conductivity and light weight. The heat dissipation members 340 and 350 are produced by extrusion molding, forging, brazing, or the like. In addition, from the viewpoint of heat dissipation, the widths of the heat dissipation members 340 and 350 are desirably wider than the widths of the sheet-shaped members 440 and 441.

The heat conduction members 453 and 454 are not particularly limited as long as the heat conduction members 453 and 454 are made of a material having a high thermal conductivity. It is preferable to use a high thermal conductive material such as metal, ceramics, or a carbon-based material in combination with a resin material. This is because the resin material compensates between the high thermal conductive material and the high thermal conductive material, between the high thermal conductive material and the heat dissipation members 340 and 350, and between the high heat conduction member and the sheet-shaped members 440 and 441, and the contact thermal resistance is reduced. The resin material is not particularly limited. For example, a material that contains silicone-based resin as a main component and has favorable electrical insulation properties is preferable.

The thermal conductivity of the heat conduction members 453 and 454 is about 5 to 8 W/m·K. A measuring method of the thermal conductivity is not particularly limited. For example, the density, the specific gravity, and the thermal diffusivity of the heat conduction member are measured, and the thermal conductivity is obtained by density×specific gravity×thermal diffusivity.

The elongation until peeling of the emitter-side heat conduction member 453 is larger than the elongation until peeling of the collector-side heat conduction member 454. The elongation of the emitter-side heat conduction member 453 is 10 to 20%, and the elongation of the collector-side heat conduction member 454 is 1 to 5%. The elongation is represented by the following expression (1).

$$Elongation = ( L - L 0 ) / L \times 100 \% \qquad ( 1 )$$

Here, L0 represents the length of a sample before a test, and L represents the length of the sample at the time of break. A measuring method of the elongation is not particularly limited. For example, the strength (value obtained by dividing a tensile load value by the cross-sectional area of a test piece) and the elongation when the test piece is pulled at a speed of 200 mm/min and then cut (broken) can be obtained according to JIS-C-2151 by using a tensile tester. That is, the elongation is a value obtained by dividing an elongation amount L−L0 between gauge marks of a broken test piece by a gauge distance L and expressing the value obtained by the division as a percentage.

The adhesive strength of the collector-side heat conduction member 454 is larger than the adhesive strength of the emitter-side heat conduction member 453. The adhesive strength of the emitter-side heat conduction member 454 is 0 to 0.05 MPa, and the adhesive strength of the collector-side heat conduction member 453 is 0.2 to 20 MPa. A measuring method of the adhesive strength is not particularly limited. For example, according to JISK6852, a test piece in which a sample is sandwiched between two adherends is made, the maximum load until the test piece is broken is recorded using a shear tester, and the adhesive strength (MPa) is obtained by dividing the maximum load by the shear area.

Here, the relationship between the elongation and the adhesive strength will be described. The adhesive strength of the heat conduction members 453 and 454 tends to decrease as the elongation increases. In other words, the elongation decreases as the adhesive strength increases. Thus, when the elongation of the emitter-side heat conduction member 453 is made larger than the elongation of the collector-side heat conduction member 454, the adhesive strength of the collector-side heat conduction member 454 is inevitably larger than the adhesive strength of the emitter-side heat conduction member 453. In the present embodiment, an example in which a material in which the elongation of the emitter-side heat conduction member 453 is larger than the elongation of the collector-side heat conduction member 454 is used, and a material in which the adhesive strength of the collector-side heat conduction member 454 is larger than the adhesive strength of the emitter-side heat conduction member 453 is used has been described. However, from the above-described relationship between the elongation and the adhesive strength, at least a material in which the elongation of the emitter-side heat conduction member 453 is larger than the elongation of the collector-side heat conduction member 454 may be used.

The heat conduction member 453 having large elongation is disposed on the emitter side, and the heat conduction member 454 having a small elongation is disposed on the collector side. The second conductor plate 431 and the fourth conductor plate 433 on the collector side are made by processing flat plates, and the first conductor plate 430 and the emitter-side third conductor plate 432 on the emitter side have a recess at the outer periphery of a region connected to the power semiconductor elements 155 and 156 in order to secure an insulation distance. Therefore, the conductor plates 431 and 433 on the collector side have high flatness, and are used as reference surfaces at the time of transfer molding or at the time of assembling with the heat dissipation member. When a plurality of electric circuit bodies 300 are sandwiched between the pair of heat dissipation members 340 and 350, the variation in the thickness of the electric circuit body 300 is concentrated on the emitter side. By disposing the heat conduction member 453 having a higher elongation on the emitter side, there is an effect that it is possible to absorb variations in thickness between the electric circuit bodies 300, and reliability and heat dissipation are secured.

The average thickness of the emitter-side heat conduction member 453 is larger than the average thickness of the collector-side heat conduction member 454. When the plurality of electric circuit bodies 300 are sandwiched between the pair of heat dissipation members 340 and 350, the average thickness of the emitter-side heat conduction member 453 is obtained by dividing the sum of the thicknesses of the heat conduction member 453 applied onto the emitter side of the plurality of electric circuit bodies 300 by the number of electric circuit bodies 300. Similarly, the average thickness of the collector-side heat conduction member 454 is obtained by dividing the sum of the thicknesses of the heat conduction member 454 applied onto the collector side of the plurality of electric circuit bodies 300 by the number of electric circuit bodies 300. Note that the thicknesses of the heat conduction members 453 and 454 are thicknesses of portions where the heat conduction members 453 and 454 overlap the conductor plates 430, 431, 432, and 433. In other words, the thickness of the heat conduction member 453 is the thickness of the heat conduction member 453 on a projection surface of the conductor plate 430, and the thickness of the heat conduction member 454 is the thickness of the heat conduction member 454 on a projection surface of the conductor plate 431.

The pressurizing member 370 (see FIG. 3) abuts on the outer side surfaces of a pair of heat dissipation members 340 and 350 and sandwiches the pair of heat dissipation members 340 and 350 to pressurize the heat conduction members 453 and 454. As a result, there is an effect that it is possible to bring the heat conduction member 454 into close contact with the electric circuit body 300 and the heat dissipation member 340 and heat dissipation and reliability are secured.

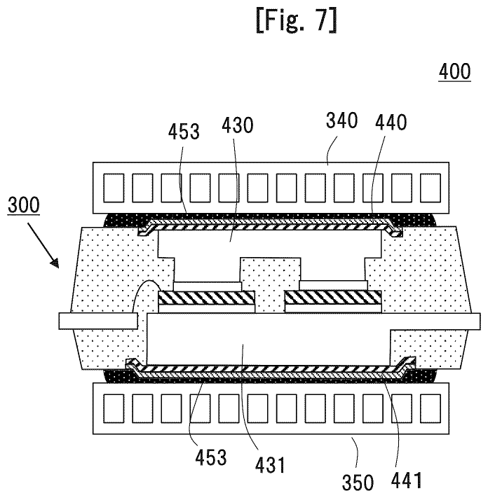

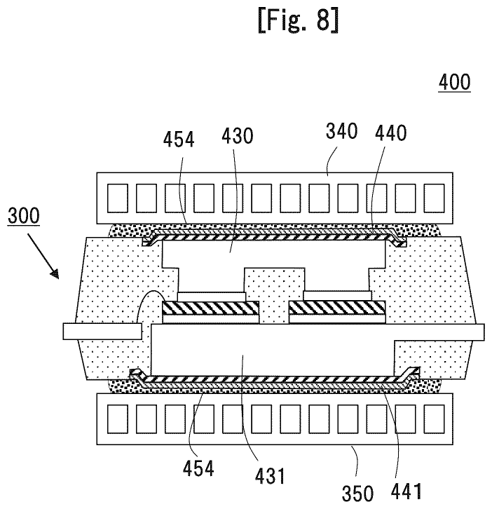

FIG. 7 is a cross-sectional view of a semiconductor device in Comparative Example 1. FIG. 8 is a cross-sectional view of a semiconductor device in Comparative Example 2. Comparative Examples 1 and 2 are provided for comparing examples in a case where the present embodiment is not applied with the present embodiment.

Comparative Example 1 illustrated in FIG. 7 is an example in which the heat conduction member 453 having a large elongation is disposed on both surfaces of the electric circuit body 300. In this case, when vibration is applied to the semiconductor device, the elongation of the heat conduction member 453 disposed on both surfaces is large, and thus the electric circuit body 300 is hardly fixed, the electric circuit body 300 easily moves in a direction in which the electric circuit bodies are arranged, and the heat conduction member 453 is peeled off, that is, the reliability of the semiconductor device is lowered.

On the other hand, in the present embodiment, the heat conduction member 453 having a large elongation is disposed on the emitter side, and the heat conduction member 454 having a small elongation is disposed on the collector side. As a result, it is possible to appropriately suppress the movement of the electric circuit body 300 and improve the reliability of the semiconductor device.

Comparative Example 2 illustrated in FIG. 8 is an example in which the heat conduction member 454 having high adhesive strength is disposed on both surfaces of the electric circuit body 300. In this case, due to a thermal cycle applied by the electric circuit body 300, the heat conduction member 454 is less likely to follow the displacement caused by the thermal expansion and the thermal contraction with the sheet-shaped members 440 and 441 having different thermal expansion coefficients, and the heat conduction member 454 and the sheet-shaped members 440 and 441 are peeled off, that is, the reliability of the semiconductor device is lowered.

On the other hand, in the present embodiment, the heat conduction member 454 having a high adhesive strength is disposed on the collector side, and the heat conduction member 454 having a low adhesive strength is disposed on the emitter side. As a result, the heat conduction member 454 appropriately follows the displacement of the electric circuit body 300 due to the thermal cycle, and it is possible to improve the reliability of the semiconductor device.

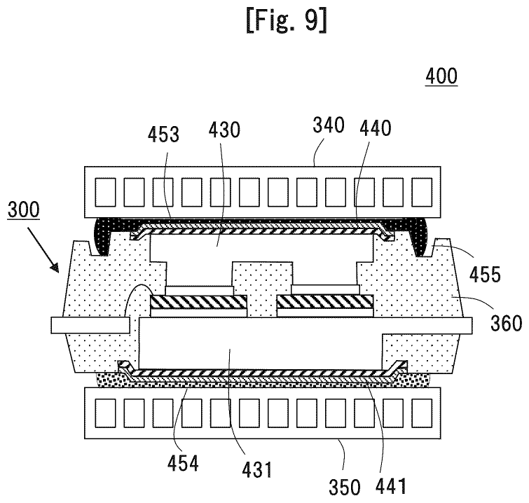

FIG. 9 is a cross-sectional view of a semiconductor device 400 in Modification Example 1. This figure is represented by a cross-sectional view similar to the X-X cross section illustrated on the left side of FIG. 6(f).

As illustrated in FIG. 9, a structure in which a recessed portion 455 is formed in the sealing member 360 on the outer peripheral side of the sheet-shaped member 440 on the emitter side. The heat conduction member 453 is disposed on the emitter side of the electric circuit body 300, and the heat conduction member 454 is disposed on the collector side of the electric circuit body 300. During the thermal cycle, the heat conduction member 453 interposed between the electric circuit body 300 and the emitter-side heat dissipation member 340 has a large elongation, and thus may protrude to the outer peripheral side. The heat conduction member 453 is often highly filled with a conductive filler such as metal or carbon for high heat dissipation, and when the heat conduction member protrudes to the outer peripheral side and hangs on the terminal, there is a concern that insulation between the heat conduction member and the conductor layer connected to the terminal is lowered due to a reaction such as migration. By forming the recessed portion 455 in the sealing member 360, the recessed portion 455 serves as a storage chamber of the heat conduction member 453, so that the heat conduction member 453 is less likely to protrude to the outer peripheral side, and there is an effect of excellent insulation.

The method of forming the recessed portion 455 is not limited, but for example, the recessed portion 455 is formed at the end of the sealing member 360 by providing the protrusion in the mold in the transfer molding process. The recessed portion 455 is formed along the outer edge of the sheet-shaped member 440. The sheet-shaped member 440 has a heat radiation surface portion 450 (see FIG. 4) overlapping with the conductor plates 430 and 432, and conducts heat to the heat dissipation member 340 via the heat conduction member 453. In the shape of the recessed portion 455, the bottom width is desirably shorter than the opening surface width. This is because it is easy to provide a protrusion whose side surface is inclined in the mold, and processing or the like is not required after formation by the mold. Further, the height of the recessed portion 455 on the sheet-shaped member 440 side is desirably higher than the height of the sealing member 360 on the end portion side. This is because, in a case where the width of the heat dissipation member 340 becomes long for heat dissipation, or in a case where the end portion of the sealing member 360 warps in the direction of the heat dissipation member 340 during a thermal cycle, the end portion of the sealing member 360 does not collide with the heat dissipation member 340, resulting in a highly reliable structure.

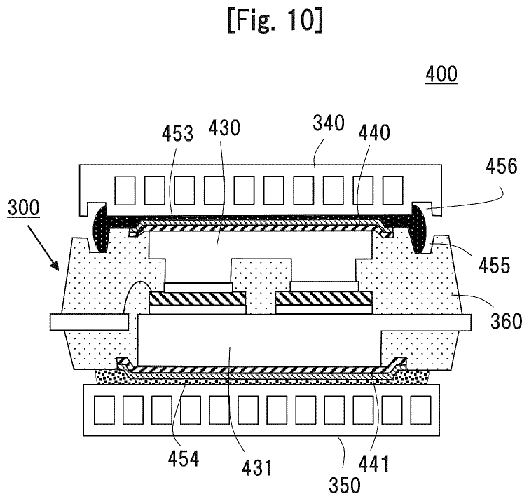

FIG. 10 is a cross-sectional view of Modification Example 2 of the semiconductor device 400. This figure is represented by a cross-sectional view similar to the X-X cross section illustrated on the left side of FIG. 6(f).

As illustrated in FIG. 10, in addition to the recessed portion 455 being formed in the sealing member 360 on the outer peripheral side of the sheet-shaped member 440, a recessed portion 456 is provided in the emitter-side heat dissipation member 340 to face the recessed portion 455. The recessed portion 456 of the heat dissipation member 340 is located outside the sheet-shaped member 440. Similarly to Modification Example 1, when the heat conduction member 453 protrudes, the volume of the recessed portion that can receive the heat conduction member 453 increases, and the effect of preventing the protrusion increases.

A method and a shape of providing the recessed portion 456 of the heat dissipation member 340 are not particularly limited. The recessed portion only needs to be formed in at least one of the sealing member 360 and the heat dissipation member 340 corresponding to the end portion of the emitter-side heat conduction member 453.

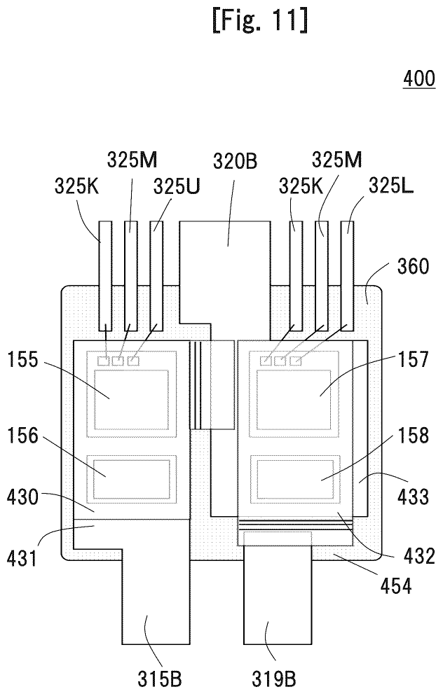

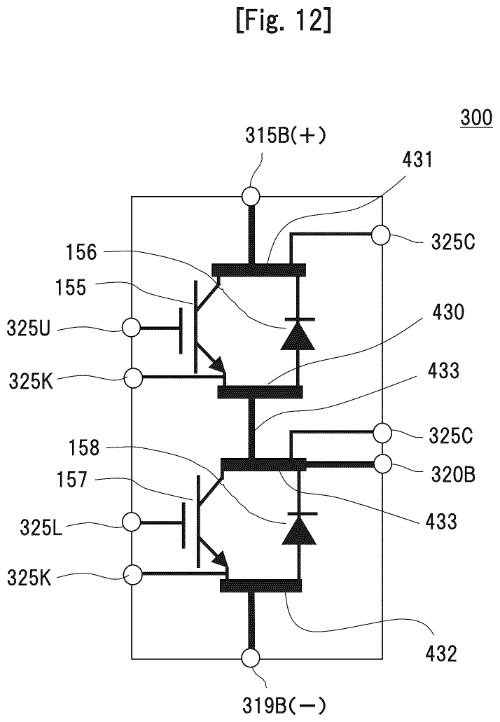

FIG. 11 is a semi-transparent plan view of the semiconductor device 400. FIG. 12 is a circuit diagram of the semiconductor device 400.

As illustrated in FIGS. 11 and 12, the positive-electrode-side terminal 315B is output from the collector side of the upper arm circuit, and is connected to the positive electrode side of a battery or a capacitor. The upper arm gate terminal 325U is output from a gate and an emitter sense of the active element 155 of the upper arm circuit. The negative-electrode-side terminal 319B is output from the emitter side of the lower arm circuit, and is connected to the negative electrode side of the battery or the capacitor, or GND. The lower arm gate terminal 325L is output from a gate and an emitter sense of the active element 157 of the lower arm circuit. The AC side terminal 320B is output from the collector side of the lower arm circuit and is connected to a motor. When the neutral point is grounded, the lower arm circuit is connected not to GND but to the negative electrode side of the capacitor.

In addition, a conductor plate (upper arm circuit emitter side) 430 and a conductor plate (upper arm circuit collector side) 431 are disposed above and below the active element 155 and the diode 156 of the power semiconductor element (upper arm circuit). A conductor plate (lower arm circuit emitter side) 432 and a conductor plate (lower arm circuit collector side) 433 are disposed above and below the active element 157 and the diode 158 of the power semiconductor element (lower arm circuit).

The semiconductor device 400 in the present embodiment has a 2in1 structure in which two arm circuits of an upper arm circuit and a lower arm circuit are integrated into one module. In addition, a structure in which a plurality of upper arm circuits and lower arm circuits are integrated into one module may be used. In this case, it is possible to reduce the number of output terminals from the semiconductor device 400 and reduce the size.

FIG. 13 is a circuit diagram of a power conversion device 200 using the semiconductor device 400.

The power conversion device 200 includes inverter circuit units 140 and 142, an auxiliary inverter circuit unit 43, and a capacitor module 500. The inverter circuit units 140 and 142 are configured by the semiconductor device 400 including a plurality of electric circuit bodies 300, and constitutes a three-phase bridge circuit by connecting the inverter circuit units 140 and 142. That is, the power conversion device 200 includes the semiconductor device 400 and converts DC power into AC power. When the current capacity is large, it is possible to handle an increase in the current capacity in a manner that the semiconductor devices 400 are further connected in parallel, and the parallel connection is performed corresponding to each phase of the three-phase inverter circuit. In addition, by connecting the active elements 155 and 157 and the diodes 156 and 158, which are power semiconductor elements built in the electric circuit body 300, in parallel, it is also possible to handle the increase in current capacity.

The inverter circuit unit 140 and the inverter circuit unit 142 have the same basic circuit configuration, and the control method and the operation are basically the same. Since the outline of the circuit operation of the inverter circuit unit 140 and the like is well known, a detailed description thereof will be omitted here.

As described above, the upper arm circuit includes the upper arm active element 155 and the upper arm diode 156 as power semiconductor elements for switching, and the lower arm circuit includes the lower arm active element 157 and the lower arm diode 158 as power semiconductor elements for switching. The active elements 155 and 157 receive a drive signal output from one or the other of two driver circuits constituting a driver circuit 174, perform switching operation, and convert DC power supplied from a battery 136 into three-phase AC power.

As described above, the upper arm active element 155 and the lower arm active element 157 include a collector electrode, an emitter electrode, and a gate electrode. The upper arm diode 156 and the lower arm diode 158 include two electrodes of a cathode electrode and an anode electrode. As illustrated in FIG. 3, cathode electrodes of the diodes 156 and 158 are electrically connected to collector electrodes of IGBTs 155 and 157, respectively, and anode electrodes thereof are electrically connected to emitter electrodes of the active elements 155 and 157, respectively. As a result, a current flows in a forward direction from the emitter electrodes of the upper arm active element 155 and the lower arm active element 157 to the collector electrodes thereof.

Note that a metal oxide semiconductor field effect transistor (MOSFET) may be used as the active element, and in this case, the upper arm diode 156 and the lower arm diode 158 are unnecessary.

The positive-electrode-side terminal 315B and the negative-electrode-side terminal 319B of each of the upper and lower arm series circuits are connected to DC terminals for capacitor connection of the capacitor module 500, respectively. AC power is generated at each connection portion between the upper arm circuit and the lower arm circuit, and the connection portion between the upper arm circuit and the lower arm circuit of each of the upper and lower arm series circuits is connected to the AC side terminal 320B of each electric circuit body 300. The AC side terminal 320B of each electric circuit body 300 for each phase is connected to the AC output terminal of the power conversion device 200, and the generated AC power is supplied to the stator winding of the motor generator 192 or 194.

A control circuit 172 generates a timing signal for controlling switching timings of the upper arm active element 155 and the lower arm active element 157 based on input information from a control device, a sensor (for example, a current sensor 180), or the like on a vehicle side. The driver circuit 174 generates a drive signal for causing the upper arm active element 155 and the lower arm active element 157 to perform a switching operation based on the timing signal output from the control circuit 172. Note that the reference signs 181, 182, and 188 denote connectors.

The upper and lower arm series circuits include a temperature sensor (not illustrated), and temperature information of the upper and lower arm series circuits is input to a microcomputer. In addition, voltage information on a DC positive side of the upper and lower arm series circuits is input to the microcomputer. The microcomputer performs overtemperature detection and overvoltage detection based on the above information. When overtemperature or overvoltage is detected, the microcomputer stops the switching operation of all the upper arm active elements 155 and the lower arm active elements 157, and protects the upper and lower arm series circuits from overtemperature or overvoltage.

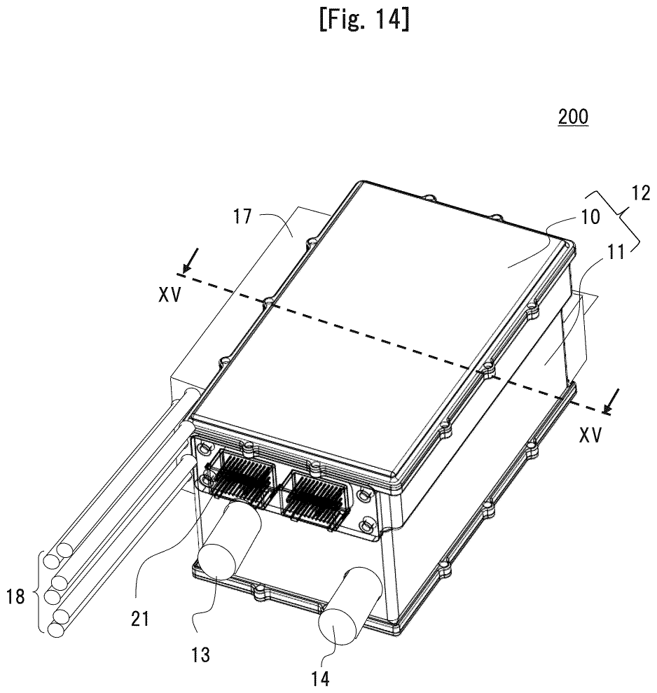

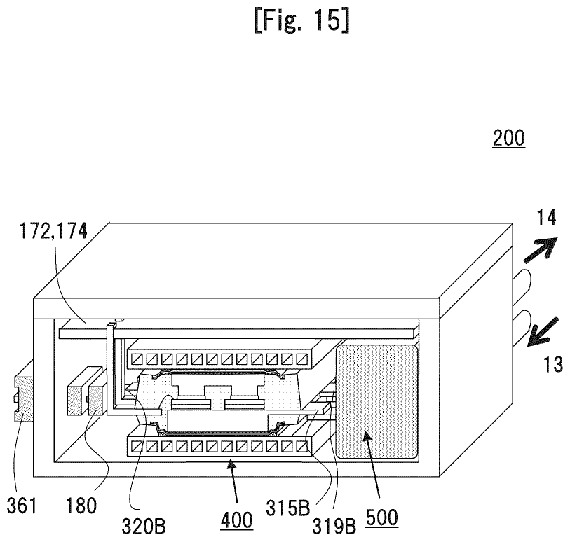

FIG. 14 is an external perspective view of the power conversion device 200. FIG. 15 is a cross-sectional view of the power conversion device illustrated in FIG. 14, taken along line XV-XV.

The power conversion device 200 includes a housing 12 that is configured by a lower case 11 and an upper case 10 and is formed in a substantially rectangular parallelepiped shape. The semiconductor device 400, the capacitor module 500, and the like are accommodated in the housing 12. The semiconductor device 400 has a cooling flow path, and a cooling water inflow pipe 13 and a cooling water outflow pipe 14 communicating with the cooling flow path protrude from one side surface of the housing 12. The upper case 10 and the lower case 11 are formed of an aluminum alloy or the like, and are sealed and fixed to the outside. The upper case 10 and the lower case 11 may be integrally configured. Since the housing 12 has a simple rectangular parallelepiped shape, attachment to a vehicle or the like is facilitated, and production is also facilitated.

A connector 17 is attached to one side surface of the housing 12 in the longitudinal direction, and an AC terminal 18 is connected to the connector 17. In addition, a connector 21 is provided on a surface from which the cooling water inflow pipe 13 and the cooling water outflow pipe 14 are drawn out.

As illustrated in FIG. 15, the semiconductor device 400 is accommodated in the housing 12. The control circuit 172 and the driver circuit 174 are disposed above the semiconductor device 400, and the capacitor module 500 is accommodated on the DC terminal side of the semiconductor device 400. By disposing the capacitor module 500 at the same height as the semiconductor device 400, it is possible to thin the power conversion device 200, and the degree of freedom in installation on the vehicle is improved. The AC side terminal 320B of the semiconductor device 400 penetrates the current sensor 180 and is bonded to a bus bar 361. Further, the positive-electrode-side terminal 315B and the negative-electrode-side terminal 319B, DC which are terminals of the semiconductor device 400, are bonded to the positive and negative electrode terminals of the capacitor module 500, respectively.

According to the embodiment described above, the following operational effects can be obtained.

(1) A semiconductor device 400 includes: a plurality of electric circuit bodies 300 having semiconductor elements 155, 156, 157, and 158; a pair of heat dissipation members 340 and 350 sandwiching the plurality of electric circuit bodies 300 from both surfaces thereof; a first heat conduction member 453 disposed between one of the heat dissipation members 340 and 350 and one surface of the plurality of electric circuit bodies 300; and a second heat conduction member 454 disposed between another of the heat dissipation members 340 and 350 and another surface of the plurality of electric circuit bodies 300, in which an elongation until peeling of the first heat conduction member 453 is larger than an elongation until peeling of the second heat conduction member 454. As a result, the reliability of the semiconductor device 400 for displacement caused by vibration or a thermal cycle is improved.

The present invention is not limited to the above-described embodiment, and other forms conceivable within the scope of the technical idea of the present invention are also included in the scope of the present invention as long as the characteristics of the present invention are not impaired. Further, the above-described embodiment and the plurality of modification examples may be combined.

### REFERENCE SIGNS LIST

10 upper case
11 lower case
12 housing
13 cooling water inflow pipe
14 cooling water outflow pipe
17, 21, 181, 182, 188 connector
18 AC terminal
43, 140, 142 inverter circuit unit
155, 156, 157, 158 power semiconductor element
172 control circuit
174 driver circuit
180 current sensor
192, 194 motor generator
200 power conversion device
300 electric circuit body
315B positive-electrode-side terminal
319B negative-electrode-side terminal
320B AC side terminal
325 signal terminal
325K Kelvin emitter signal terminal
325L lower arm gate terminal
325M mirror emitter signal terminal
325U upper arm gate terminal
340, 350 heat dissipation member
360 sealing member
370 pressurizing member
400 semiconductor device
430, 431, 432, 433 conductor plate
440, 441 sheet-shaped member
442, 443 resin insulating layer
444 metal foil
450 heat dissipation surface portion
451 margin portion
452 buried portion
453, 454 heat conduction member
455 recessed portion of sealing member
456 recessed portion of heat dissipation member
500 capacitor module
601 transfer module device

1. A semiconductor device comprising:
a plurality of electric circuit bodies each having a semiconductor element; a pair of heat dissipation members sandwiching the plurality of electric circuit bodies from both surfaces thereof; a first heat conduction member disposed between one of the heat dissipation members and one surface of the plurality of electric circuit bodies; and a second heat conduction member disposed between another of the heat dissipation members and another surface of the plurality of electric circuit bodies,
wherein an elongation until peeling of the first heat conduction member is larger than an elongation until peeling of the second heat conduction member.

2. The semiconductor device according to claim 1, wherein an adhesive strength of the second heat conduction member is larger than an adhesive strength of the first heat conduction member.

3. The semiconductor device according to claim 1, wherein the first heat conduction member is disposed on an emitter side of the semiconductor element, and the second heat conduction member is disposed on a collector side of the semiconductor element.

4. The semiconductor device according to claim 3, wherein a thickness of the first heat conduction member is larger than a thickness of the second heat conduction member.

5. The semiconductor device according to claim 1, wherein the elongation of the first heat conduction member is 10 to 20%, and the elongation of the second heat conduction member is 1 to 5%.

6. The semiconductor device according to claim 2, wherein the adhesive strength of the first heat conduction member is 0 to 0.05 MPa, and the adhesive strength of the second heat conduction member is 0.2 to 20 MPa.

7. The semiconductor device according to claim 1, wherein thermal conductivity of the first heat conduction member and the second heat conduction member is 5 to 8 W/m·K.

8. The semiconductor device according to claim 1, wherein the electric circuit body is sealed with a sealing member, and a recessed portion is formed in at least one of the sealing member and the heat dissipation member to correspond to an end portion of the first heat conduction member.

9. The semiconductor device according to claim 1, further comprising:
a pressurizing member that abuts on each of outer side surfaces of the pair of heat dissipation members and sandwiches the pair of heat dissipation members to pressurize the first heat conduction member and the second heat conduction member.

10. A power conversion device comprising the semiconductor device according to claim 1,
wherein the power conversion device converts DC power into AC power.
